(19) United States
(12) Patent Application Publication
(10) Pub. No.: US 2024/0176193 A1
(43) Pub. Date: May 30, 2024

(54) LIQUID CRYSTAL OPTICAL ELEMENT

(71) Applicants: Japan Display Inc., Tokyo (JP); OSAKA UNIVERSITY, Osaka (JP)

(72) Inventors: Koichi IGETA, Tokyo (JP); Shinichiro OKA, Tokyo (JP); Yasushi TOMIOKA, Tokyo (JP); Junji KOBASHI, Tokyo (JP); Hiroyuki YOSHIDA, Suita-shi (JP)

(73) Assignees: Japan Display Inc., Tokyo (JP); OSAKA UNIVERSITY, Suita-shi, Osaka (JP)

(21) Appl. No.: 18/431,141

(22) Filed: Feb. 2, 2024

Related U.S. Application Data
(63) Continuation of application No. PCT/JP2022/021570, filed on May 26, 2022.

(30) Foreign Application Priority Data
Aug. 4, 2021 (JP) 2021-128319

(51) Int. Cl. G02F 1/1347; G02F 1/01; G02F 1/1337; G02F 1/137

(52) U.S. Cl. CPC G02F 1/1347; G02F 1/011; G02F 1/133711; G02F 1/13718; G02F 2201/50

(57) ABSTRACT

According to one embodiment, a liquid crystal optical element includes an optical waveguide including a first main surface and a second main surface opposed to the first main surface, a first alignment film disposed on the second main surface, a first liquid crystal layer which overlaps the first alignment film, which comprises a first cholesteric liquid crystal, and which reflects at least part of light incident through the optical waveguide toward the optical waveguide, a second alignment film which overlaps the first liquid crystal layer, and a second liquid crystal layer which overlaps the second alignment film, which comprises a second cholesteric liquid crystal, and which reflects at least part of light incident through the optical waveguide toward the optical waveguide.

### CROSS-REFERENCE TO RELATED APPLICATIONS

This application is a Continuation Application of PCT Application No. PCT/JP2022/021570, filed May 26, 2022 and based upon and claiming the benefit of priority from Japanese Patent Application No. 2021-128319, filed Aug. 4, 2021, the entire contents of all of which are incorporated herein by reference.

### FIELD

Embodiments described herein relate generally to a liquid crystal optical element.

### BACKGROUND

For example, liquid crystal polarization gratings for which liquid crystal materials are used have been proposed. Such a liquid crystal polarization grating divides incident light into zero-order diffracted light and first-order diffracted light, when light of a wavelength λ is incident thereon. In optical elements for which liquid crystal materials are used, it is necessary to adjust parameters such as the refractive anisotropy Δn of a liquid crystal layer (difference between the refractive index ne for extraordinary light and the refractive index no for ordinary light of the liquid crystal layer) and the thickness d of the liquid crystal layer, as well as the grating period.

### BRIEF DESCRIPTION OF THE DRAWINGS

FIG. 1 is a cross-sectional view schematically illustrating a liquid crystal optical element 100 according to Embodiment 1.

FIG. 2 is a cross-sectional view schematically illustrating the structure of a first liquid crystal layer 3A.

FIG. 3 is a plan view schematically illustrating the liquid crystal optical element 100.

FIG. 4 is a diagram for explaining a method for manufacturing the liquid crystal optical element 100.

FIG. 5 is a diagram illustrating measurement results of the transmission spectrum of the liquid crystal optical element 100 before and after the formation of a second alignment film 2B.

FIG. 6 is a cross-sectional view schematically illustrating a liquid crystal optical element 100 according to Embodiment 2.

FIG. 7 is a cross-sectional view schematically illustrating a liquid crystal optical element 100 according to Embodiment 3.

FIG. 8 is a cross-sectional view schematically illustrating a liquid crystal optical element 100 according to Embodiment 4.

FIG. 9 is a cross-sectional view schematically illustrating a liquid crystal optical element 100 according to Embodiment 5.

FIG. 10 is a cross-sectional view schematically illustrating a liquid crystal optical element 100 according to Embodiment 6.

FIG. 11 is a diagram illustrating an example of the outside of a photovoltaic cell device 200.

FIG. 12 is a diagram for explaining the operation of the photovoltaic cell device 200.

### DETAILED DESCRIPTION

Embodiments described herein aim to provide a liquid crystal optical element which can achieve desired reflective performance.

In general, according to one embodiment, a liquid crystal optical element comprises an optical waveguide comprising a first main surface and a second main surface opposed to the first main surface, a first alignment film disposed on the second main surface, a first liquid crystal layer which overlaps the first alignment film, which comprises a first cholesteric liquid crystal, and which reflects at least part of light incident through the optical waveguide toward the optical waveguide, a second alignment film which overlaps the first liquid crystal layer, and a second liquid crystal layer which overlaps the second alignment film, which comprises a second cholesteric liquid crystal, and which reflects at least part of light incident through the optical waveguide toward the optical waveguide.

According to another embodiment, a liquid crystal optical element comprises an optical waveguide comprising a first main surface and a second main surface opposed to the first main surface, a first alignment film disposed on the second main surface, a first liquid crystal layer which overlaps the first alignment film, which comprises a first cholesteric liquid crystal, and which reflects at least part of light incident through the optical waveguide toward the optical waveguide, a protective layer which overlaps the first liquid crystal layer, a second alignment film which overlaps the protective layer, and a second liquid crystal layer which overlaps the second alignment film, which comprises a second cholesteric liquid crystal, and which reflects at least part of light incident through the optical waveguide toward the optical waveguide.

According to yet another embodiment, a liquid crystal optical element comprises an optical waveguide comprising a first main surface and a second main surface opposed to the first main surface, a first alignment film disposed on the second main surface, a first liquid crystal layer which overlaps the first alignment film, which comprises a first cholesteric liquid crystal, and which reflects at least part of light incident through the optical waveguide toward the optical waveguide, a first protective layer which overlaps the first liquid crystal layer, a second alignment film which overlaps the first protective layer, a second liquid crystal layer which overlaps the second alignment film, which comprises a second cholesteric liquid crystal, and which reflects at least part of light incident through the optical waveguide toward the optical waveguide, a second protective layer which overlaps the second liquid crystal layer, a third alignment film which overlaps the second protective layer, a third liquid crystal layer which overlaps the third alignment film, which comprises a third cholesteric liquid crystal, and which reflects at least part of light incident through the optical waveguide toward the optical waveguide, a third protective layer which overlaps the third liquid crystal layer, a fourth alignment film which overlaps the third protective layer, and a fourth liquid crystal layer which overlaps the fourth alignment film, which comprises a fourth cholesteric liquid crystal, and which reflects at least part of light incident through the optical waveguide toward the optical waveguide.

According to the embodiments, a liquid crystal optical element which can achieve desired reflective performance can be provided.

Embodiments will be described hereinafter with reference to the accompanying drawings. The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

In the drawings, an X-axis, a Y-axis, and a Z-axis orthogonal to each other are described to facilitate understanding as necessary. A direction along the Z-axis is referred to as a Z direction or a first direction A1, a direction along the Y-axis is referred to as a Y direction or a second direction A2, and a direction along the X-axis is referred to as an X direction or a third direction A3. A plane defined by the X-axis and the Y-axis is referred to as an X-Y plane, a plane defined by the X-axis and the Z-axis is referred to as an X-Z plane, and a plane defined by the Y-axis and the Z-axis is referred to as a Y-Z plane.

### Embodiment 1

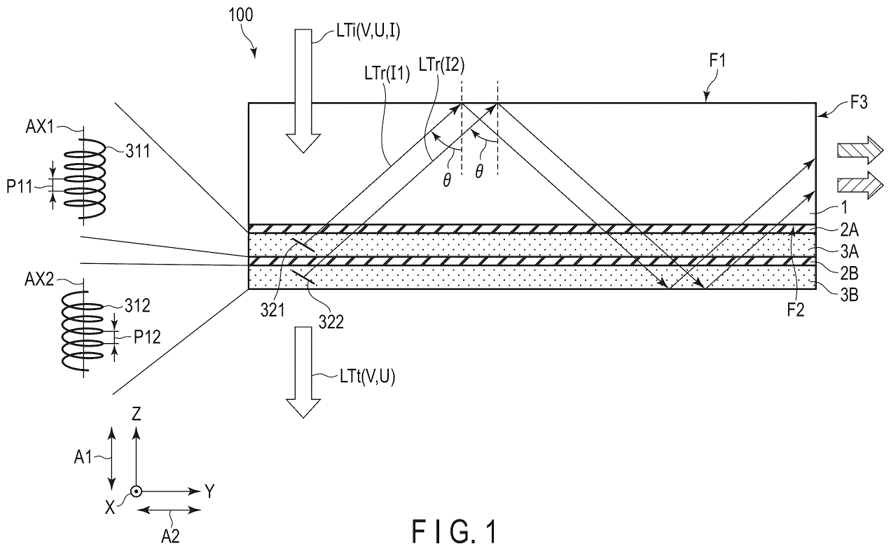

FIG. 1 is a cross-sectional view schematically illustrating a liquid crystal optical element 100 according to Embodiment 1.

The liquid crystal optical element 100 comprises an optical waveguide 1, a first alignment film 2A, a first liquid crystal layer 3A, a second alignment film 2B, and a second liquid crystal layer 3B.

The optical waveguide 1 is composed of a transparent member that transmits light, for example, a transparent glass plate or a transparent synthetic resin plate. The optical waveguide 1 may be composed of, for example, a transparent synthetic resin plate having flexibility. The optical waveguide 1 can assume an arbitrary shape. For example, the optical waveguide 1 may be curved. The refractive index of the optical waveguide 1 is greater than, for example, the refractive index of air. The optical waveguide 1 functions as, for example, a windowpane.

In the present specification, “light” includes visible light and invisible light. For example, the wavelength of the lower limit of the visible light range is greater than or equal to 360 nm but less than or equal to 400 nm, and the wavelength of the upper limit of the visible light range is greater than or equal to 760 nm but less than or equal to 830 nm. Visible light includes a first component (blue component) of a first wavelength band (for example, 400 nm to 500 nm), a second component (green component) of a second wavelength band (for example, 500 nm to 600 nm), and a third component (red component) of a third wavelength band (for example, 600 nm to 700 nm). Invisible light includes ultraviolet rays of a wavelength band shorter than the first wavelength band and infrared rays of a wavelength band longer than the third wavelength band.

In the present specification, to be “transparent” should preferably be to be colorless and transparent. Note that to be “transparent” may be to be translucent or to be colored and transparent. The optical waveguide 1 is formed in the shape of a flat plate along the X-Y plane, and comprises a first main surface F1, a second main surface F2, and a side surface F3. The first main surface F1 and the second main surface F2 are surfaces substantially parallel to the X-Y plane and are opposed to each other in the first direction A1. The side surface F3 is a surface extending in the first direction A1. In the example illustrated in FIG. 1, the side surface F3 is a surface substantially parallel to the X-Z plane, but the side surface F3 includes a surface substantially parallel to the Y-Z plane.

The first alignment film 2A is disposed on the second main surface F2. The first alignment film 2A is a horizontal alignment film having alignment restriction force along the X-Y plane.

The first liquid crystal layer 3A overlaps the first alignment film 2A in the first direction A1. That is, the first alignment film 2A is located between the optical waveguide 1 and the first liquid crystal layer 3A, and contacts the optical waveguide 1 and the first liquid crystal layer 3A.

The second alignment film 2B overlaps the first liquid crystal layer 3A in the first direction A1. That is, the first liquid crystal layer 3A is located between the first alignment film 2A and the second alignment film 2B, and contacts the first alignment film 2A and the second alignment film 2B. The second alignment film 2B is a horizontal alignment film having alignment restriction force along the X-Y plane.

The second liquid crystal layer 3B overlaps the second alignment film 2B in the first direction A1. That is, the second alignment film 2B is located between the first liquid crystal layer 3A and the second liquid crystal layer 3B, and contacts the first liquid crystal layer 3A and the second liquid crystal layer 3B.

The first alignment film 2A and the second alignment film 2B are, for example, optical alignment films for which alignment treatment can be performed by light irradiation, but may be alignment films for which alignment treatment is performed by rubbing or may be alignment films having minute irregularities. As the optical alignment films, optical alignment films of any one of a photodecomposition type, a photodimerization type, and a photoisomerization type can be applied.

Examples of the material forming the optical alignment films of the photodecomposition type include a compound including an alicyclic structure such as a cyclobutane skeleton as a photo-alignable group, as well as polyimide obtained by making diamine and tetracarboxylic acid or their derivatives react.

Examples of the material forming the optical alignment films of the photodimerization type include a compound including a structural moiety such as a cinnamoyl group, a chalcone group, a coumarin group, or an anthracene group as a photo-alignable group. Of these compounds, a compound including a cinnamoyl group is preferable, as it has high transparency in the visible light range and exhibits high reactivity.

Examples of the material forming the optical alignment films of the photoisomerization type include a compound including a structural moiety such as an azobenzene structure or a stilbene structure as a photo-alignable group. Of these compounds, a compound including an azobenzene structure is preferable, as it exhibits high reactivity.

The first liquid crystal layer 3A and the second liquid crystal layer 3B reflect at least part of light LT1 incident from the first main surface F1 side toward the optical waveguide 1.

In Embodiment 1, the first liquid crystal layer 3A comprises a first cholesteric liquid crystal 311 turning in a first turning direction. The first cholesteric liquid crystal 311 has a helical axis AX1 substantially parallel to the first direction A1 and has a helical pitch P11 in the first direction A1.

The second liquid crystal layer 3B comprises a second cholesteric liquid crystal 312 turning in a second turning direction opposite to the first turning direction. The second cholesteric liquid crystal 312 has a helical axis AX2 substantially parallel to the first direction A1 and has a helical pitch P12 in the first direction A1. The helical axis AX1 is parallel to the helical axis AX2. The helical pitch P11 is equal to the helical pitch P12.

The first liquid crystal layer 3A and the second liquid crystal layer 3B reflect circularly polarized light of a selective reflection band determined according to the helical pitch and the refractive anisotropy, of light LTi incident through the optical waveguide 1. In the present specification, ‘reflection’ in each of the liquid crystal layers involves diffraction inside the liquid crystal layers.

In the first liquid crystal layer 3A, the first cholesteric liquid crystal 311 forms a reflective surface 321 which reflects first circularly polarized light corresponding to the first turning direction, of the selective reflection band.

In the second liquid crystal layer 3B, the second cholesteric liquid crystal 312 forms a reflective surface 322 which reflects second circularly polarized light corresponding to the second turning direction, of the selective reflection band. Second circularly polarized light is light circularly polarized in the opposite direction to that of first circularly polarized light.

For example, the first cholesteric liquid crystal 311 and the second cholesteric liquid crystal 312 are both formed to reflect infrared rays I as the selective reflection band, as schematically illustrated in an enlarged manner. That is, the first cholesteric liquid crystal 311 is configured to reflect first circularly polarized light I1 of infrared rays I, and the second cholesteric liquid crystal 312 is configured to reflect second circularly polarized light 12 of infrared rays I. In the present specification, circularly polarized light may be precise circularly polarized light or may be circularly polarized light approximate to elliptically polarized light.

While the example in which infrared rays I are reflected has been described here, the first cholesteric liquid crystal 311 and the second cholesteric liquid crystal 312 may be configured to reflect visible light V or may be configured to reflect ultraviolet rays U.

The relationship between the thicknesses of the thin films constituting the liquid crystal optical element 100 is as follows.

The respective thicknesses of the first alignment film 2A and the second alignment film 2B are 5 nm to 300 nm and should preferably be 10 nm to 200 nm.

The respective thicknesses of the first liquid crystal layer 3A and the second liquid crystal layer 3B are 1 μm to 10 μm and should preferably be 2 μm to 7 μm.

The optical action of the liquid crystal optical element 100 in Embodiment 1 illustrated in FIG. 1 will be described next.

Light LTi incident on the liquid crystal optical element 100 includes, for example, visible light V, ultraviolet rays U, and infrared rays I.

In the example illustrated in FIG. 1, to facilitate understanding, it is assumed that light LTi is incident substantially perpendicularly to the optical waveguide 1. The angle of incidence of light LTi to the optical waveguide 1 is not particularly limited. For example, light LTi may be incident on the optical waveguide 1 at angles of incidence different from each other.

Light LTi enters the inside of the optical waveguide 1 from the first main surface F1, is emitted from the second main surface F2, is transmitted through the first alignment film 2A, and is incident on the first liquid crystal layer 3A. Then, the first liquid crystal layer 3A reflects first circularly polarized light I1 of infrared rays I of light LTi toward the optical waveguide 1 and transmits other light LTt.

Light LTt transmitted through the first liquid crystal layer 3A is transmitted through the second alignment film 2B and is incident on the second liquid crystal layer 3B. Then, the second liquid crystal layer 3B reflects second circularly polarized light 12 of infrared rays I of light LTt toward the optical waveguide 1 and reflects other light LTt. Light LTt transmitted through the second liquid crystal layer 3B includes visible light V and ultraviolet rays U.

The first liquid crystal layer 3A reflects first circularly polarized light I1 toward the optical waveguide 1 at an angle θ of entry which satisfies the optical waveguide conditions in the optical waveguide 1. Similarly, the second liquid crystal layer 3B reflects second circularly polarized light 12 toward the optical waveguide 1 at the angle θ of entry which satisfies the optical waveguide conditions in the optical waveguide 1.

The angle θ of entry here corresponds to an angle greater than or equal to the critical angle θc which causes total reflection at the interface between the optical waveguide 1 and the air. The angle θ of entry represents an angle to a perpendicular line orthogonal to the optical waveguide 1.

If the optical waveguide 1, the first alignment film 2A, the first liquid crystal layer 3A, the second alignment film 2B, and the second liquid the stacked layer body of these can be a single optical waveguide body. In this case, light LTr is guided toward the side surface F3 while being reflected repeatedly at the interface between the optical waveguide 1 and the air and the interface between the second liquid crystal layer 3B and the air.

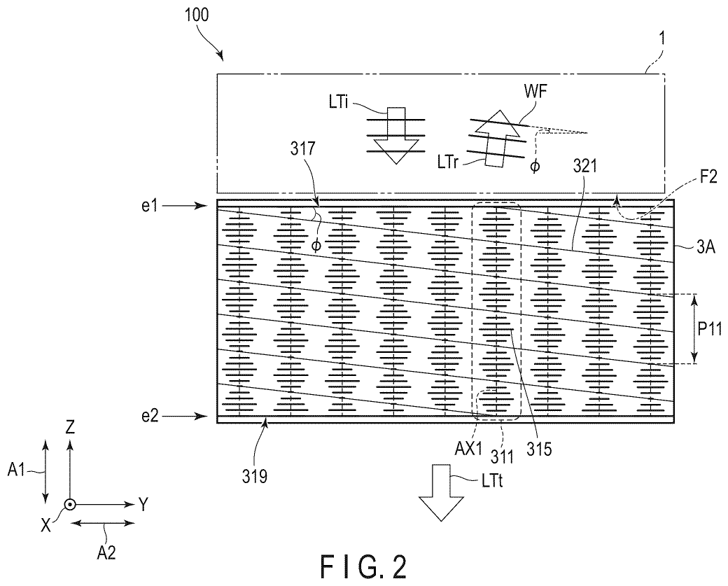

FIG. 2 is a cross-sectional view schematically illustrating the structure of the first liquid crystal layer 3A.

The optical waveguide 1 is indicated by a long dashed and double-short dashed line. In addition, the illustration of the first alignment film, the second alignment film, and the second liquid crystal layer illustrated in FIG. 1 is omitted.

The first liquid crystal layer 3A comprises first cholesteric liquid crystals 311 as helical structures. Each of the first cholesteric liquid crystals 311 has the helical axis AX1 substantially parallel to the first direction A1. The helical axis AX1 is substantially perpendicular to the second main surface F2 of the optical waveguide 1.

Each of the first cholesteric liquid crystals 311 has the helical pitch P11 in the first direction A1. The helical pitch P11 indicates one cycle (360 degrees) of the helix. The helical pitch P11 is constant with hardly any change in the first direction A1. Each of the first cholesteric liquid crystals 311 includes liquid crystal molecules 315. The liquid crystal molecules 315 are stacked helically in the first direction A1 while turning.

The first liquid crystal layer 3A comprises a first boundary surface 317 opposed to the second main surface F2 in the first direction A1, a second boundary surface 319 on the opposite side to the first boundary surface 317, and reflective surfaces 321 between the first boundary surface 317 and the second boundary surface 319. The first boundary surface 317 is a surface through which light LTi transmitted through the optical waveguide 1 enters the first liquid crystal layer 3A. Each of the first boundary surface 317 and the second boundary surface 319 is substantially perpendicular to the helical axis AX1 of the first cholesteric liquid crystals 311. Each of the first boundary surface 317 and the second boundary surface 319 is substantially parallel to the optical waveguide 1 (or the second main surface F2).

The first boundary surface 317 includes liquid crystal molecules 315 located at one end e1 of both ends of the first cholesteric liquid crystals 311. The first boundary surface 317 corresponds to a boundary surface between the first alignment film not illustrated in the figure and the first liquid crystal layer 3A.

The second boundary surface 319 includes liquid crystal molecules 315 located at the other end e2 of both ends of the first cholesteric liquid crystals 311. The second boundary surface 319 corresponds to a boundary surface between the first liquid crystal layer 3A and the second alignment film not illustrated in the figure.

In the example illustrated in FIG. 2, the reflective surfaces 321 are substantially parallel to each other. The reflective surfaces 321 are inclined with respect to the first boundary surface 317 and the optical waveguide 1 (or the second main surface F2), and have a substantially planar shape extending in one direction. The reflective surfaces 321 selectively reflect light LTr, which is part of light LTi incident through the first boundary surface 317, in accordance with Bragg's law. Specifically, the reflective surfaces 321 reflect light LTr such that the wave front WF of light LTr becomes substantially parallel to the reflective surfaces 321. More specifically, the reflective surfaces 321 reflect light LTr in accordance with the angles φ of inclination of the reflective surfaces 321 with respect to the first boundary surface 317.

The reflective surfaces 321 can be defined as follows. That is, the refractive index for light (for example, circularly polarized light) of a predetermined wavelength selectively reflected in the first liquid crystal layer 3A changes gradually as the light travels through the inside of the first liquid crystal layer 3A. Thus, Fresnel reflection occurs gradually in the first liquid crystal layer 3A. In addition, Fresnel reflection occurs most strongly at the position where the refractive index for light changes most greatly in the first cholesteric liquid crystals 311. That is, the reflective surfaces 321 correspond to the surfaces where Fresnel reflection occurs most strongly in the first liquid crystal layer 3A.

The alignment directions of the respective liquid crystal molecules 315 of first cholesteric liquid crystals 311 adjacent to each other in the second direction A2 of the first cholesteric liquid crystals 311 are different from each other. In addition, the respective spatial phases of first cholesteric liquid crystals 311 adjacent to each other in the second direction A2 of the first cholesteric liquid crystals 311 are different from each other. The reflective surfaces 321 correspond to the surfaces formed by the liquid crystal molecules 315 whose alignment directions are the same, or the surfaces along which the spatial phases are the same (equiphase wave surfaces). That is, each of the reflective surfaces 321 is inclined with respect to the first boundary surface 317 or the optical waveguide 1.

The shape of the reflective surfaces 321 is not limited to a planar shape as illustrated in FIG. 2, but may be a curved surface such as a concave shape or a convex shape and is not particularly limited. In addition, part of the reflective surfaces 321 may have irregularities, or the angles φ of inclination of the reflective surfaces 321 may not be uniform, or the reflective surfaces 321 may not be arranged regularly. According to the spatial phase distribution of the first cholesteric liquid crystals 311, the reflective surfaces 321 having an arbitrary shape can be formed.

FIG. 2 illustrates the liquid crystal molecules 315 aligned in the average alignment directions as representatives of the liquid crystal molecules 315 located in the X-Y plane, for simplification of the drawing.

The first cholesteric liquid crystals 311 reflect circularly polarized light of the same turning direction as that of the first cholesteric liquid crystals 311, of light of a predetermined wavelength λ included in the selective reflection band Δλ. For example, if the turning direction of the first cholesteric liquid crystals 311 is right-handed, they reflect right-handed circularly polarized light and transmit left-handed circularly polarized light, of light of the predetermined wavelength λ. Similarly, if the turning direction of the first cholesteric liquid crystals 311 is left-handed, they reflect left-handed circularly polarized light and transmit right-handed circularly polarized light, of light of the predetermined wavelength λ.

While the first cholesteric liquid crystals 311 and the reflective surfaces 321 in the first liquid crystal layer 3A have been described here, the second liquid crystal layer 3B is formed in the same way as the first liquid crystal layer 3A, and the description of second cholesteric liquid crystals 312 and reflective surfaces 322 is omitted.

The selective reflection band Δλ of cholesteric liquid crystals 31 for perpendicularly incident light is generally expressed as “no*P to ne*P”, where P represents the helical pitch of the cholesteric liquid crystals 31, ne represents the refractive index for extraordinary light of liquid crystal molecules 315, and no represents the refractive index for ordinary light of the liquid crystal molecules 315. Specifically, the selective reflection band Δλ of the cholesteric liquid crystals 31 varies in the range of “no*P to ne*P” according to the angle φ of inclination of a reflective surface, the angle of incidence on the first boundary surface 317, etc.

For example, a case where the helical pitch P11 of the first cholesteric liquid crystals 311 and the helical pitch P12 of the second cholesteric liquid crystals 312 are adjusted to set the selective reflection band Δλ to the wavelength band of infrared rays will be described. In order to increase the reflectance at the reflective surfaces 321 of the first liquid crystal layer 3A and the reflective surfaces 322 of the second liquid crystal layer 3B, it is desirable that the thickness in the first direction A1 of the first liquid crystal layer 3A and the thickness in the first direction A1 of the second liquid crystal layer 3B be set to approximately several times to ten times the helical pitch. Assuming that the refractive anisotropy Δn is approximately 0.2, the helical pitch is approximately 500 nm to set the wavelength band of infrared rays as the selective reflection band. In this case, the respective thicknesses of the first liquid crystal layer 3A and the second liquid crystal layer 3B are approximately 1 to 10 μm and should preferably be 2 to 7 μm.

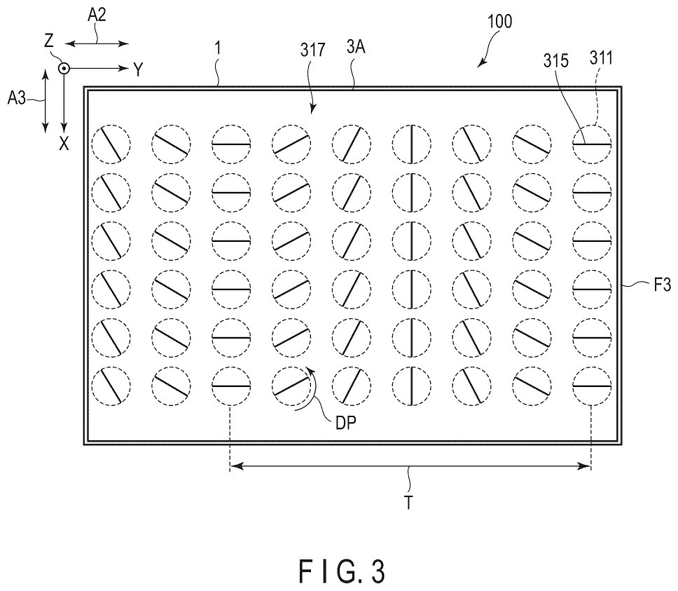

FIG. 3 is a plan view schematically illustrating the liquid crystal optical element 100.

FIG. 3 shows an example of the spatial phases of the first cholesteric liquid crystals 311. The spatial phases here are illustrated as the alignment directions of the liquid crystal molecules 315 located in the first boundary surface 317 of the liquid crystal molecules 315 included in the first cholesteric liquid crystals 311.

As for the first cholesteric liquid crystals 311 arranged in the second direction A2, the alignment directions of the liquid crystal molecules 315 located in the first boundary surface 317 are different from each other. That is, the spatial phases of the first cholesteric liquid crystals 311 in the first boundary surface 317 are different in the second direction A2.

In contrast, as for the first cholesteric liquid crystals 311 arranged in the third direction A3, the alignment directions of the liquid crystal molecules 315 located in the first boundary surface 317 are substantially identical. That is, the spatial phases of the first cholesteric liquid crystals 311 in the first boundary surface 317 are substantially identical in the third direction A3.

In particular, as for the first cholesteric liquid crystals 311 arranged in the second direction A2, the respective alignment directions of the liquid crystal molecules 315 differ by equal angles. That is, in the first boundary surface 317, the alignment directions of the liquid crystal molecules 315 arranged in the second direction A2 change linearly. Accordingly, the spatial phases of the first cholesteric liquid crystals 311 arranged in the second direction A2 change linearly in the second direction A2. As a result, the reflective surfaces 321 inclined with respect to the first boundary surface 317 and the optical waveguide 1 are formed as in the first liquid crystal layer 3A illustrated in FIG. 2. The phrase ‘linearly change’ here means, for example, that the amount of change of the alignment directions of the liquid crystal molecules 315 is represented by a linear function. The alignment directions of the liquid crystal molecules 315 here correspond to the directions of the major axes of the liquid crystal molecules 315 in the X-Y plane. The alignment directions of the liquid crystal molecules 315 as described above are controlled by alignment treatment performed for the first alignment film 2A.

Here, as illustrated in FIG. 3, in one plane, the interval between two liquid crystal molecules 315 between which the alignment directions of the liquid crystal molecules 315 change by 180 degrees in the second direction A2 is defined as a cycle T. In FIG. 3, DP denotes the turning direction of the liquid crystal molecules 315. The angles q of inclination of the reflective surfaces 321 illustrated in FIG. 2 is set as appropriate by the cycle T and the helical pitch P11.

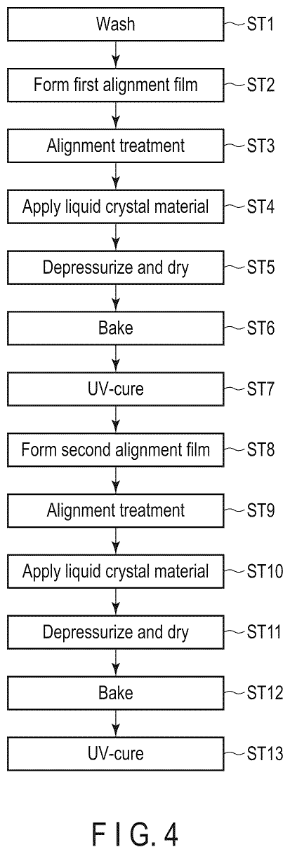

A method for manufacturing the liquid crystal optical element 100 will be described next with reference to FIG. 4.

First, the optical waveguide 1 is washed (step ST1).

Then, the first alignment film 2A is formed on the second main surface F2 of the optical waveguide 1 (step ST2). After that, the alignment treatment of the first alignment film 2A is performed (step ST3).

Then, a liquid crystal material (monomeric material for forming the first cholesteric liquid crystals) is applied to the top (upper surface on the opposite side to the surface that contacts the optical waveguide 1) of the first alignment film 2A (step ST4). Liquid crystal molecules included in the liquid crystal material are aligned in a predetermined direction in accordance with the direction of the alignment treatment of the first alignment film 2A. After that, the liquid crystal material is dried by depressurizing the inside of a chamber (step ST5), and the liquid crystal material is further baked (step ST6). Then, the liquid crystal material is irradiated with ultraviolet rays and the liquid crystal material is cured (step ST7). In this way, the first liquid crystal layer 3A comprising the first cholesteric liquid crystals 311 is formed.

Then, the second alignment film 2B is formed on the surface of the cured first liquid crystal layer 3A (step ST8). After that, the alignment treatment of the second alignment film 2B is performed (step ST9).

Then, a liquid crystal material (monomeric material for forming the second cholesteric liquid crystals) is applied to the top (upper surface on the opposite side to the surface that contacts the first liquid crystal layer 3A) of the second alignment film 2B (step ST10). Liquid crystal molecules included in the liquid crystal material are aligned in a predetermined direction in accordance with the direction of the alignment treatment of the second alignment film 2B. After that, the liquid crystal material is dried by depressurizing the inside of a chamber (step ST11), and the liquid crystal material is further baked (step ST12). Then, the liquid crystal material is irradiated with ultraviolet rays and the liquid crystal material is cured (step ST13). In this way, the second liquid crystal layer 3B comprising the second cholesteric liquid crystals 312 is formed.

To form alignment films and liquid crystal layers in three or more layers, step ST8 to step ST13, described above, are performed repeatedly.

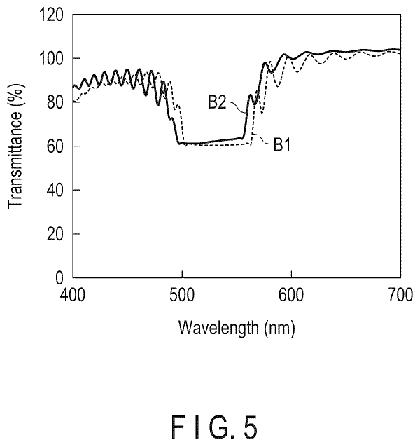

FIG. 5 is a diagram illustrating measurement results of the transmission spectrum of the liquid crystal optical element 100 before and after the formation of the second alignment film 2B.

The horizontal axis of the figure represents wavelength (nm) and the vertical axis of the figure represents transmittance (%).

B1 in the figure represents the measurement result of the transmission spectrum before the formation of the second alignment film 2B. That is, the transmission spectrum of the stacked layer body of the optical waveguide 1, the first alignment film 2A, and the first liquid crystal layer 3A is measured, and its measurement result is represented by B1 in the figure. In the measurement test here, the first liquid crystal layer 3A is configured to reflect a second component (green component) of visible light.

B2 in the figure represents the measurement result of the transmission spectrum after the formation of the second alignment film 2B. That is, the transmission spectrum of the stacked layer body of the optical waveguide 1, the first alignment film 2A, the first liquid crystal layer 3A, and the second alignment film 2B is measured, and its measurement result is represented by B2 in the figure.

If the components of the second alignment film 2B penetrate the first liquid crystal layer 3A at the time of the formation of the second alignment film 2B on the surface of the cured first liquid crystal layer 3A, the helical pitch of the first cholesteric liquid crystals 311 enlarges in the first direction A1 and the selective reflection band Δλ may shift to a long wavelength side.

The measurement results illustrated in FIG. 5 have confirmed that before and after the formation of the second alignment film 2B, the selective reflection band Δλ was 500 nm to 560 nm and hardly changed. That is, it has been confirmed that the penetration of the first liquid crystal layer 3A by the components of the second alignment film 2B was suppressed and the enlargement of the helical pitch of the first cholesteric liquid crystals 311 was suppressed.

According to Embodiment 1 as described above, the selective reflection band Δλ of the first liquid crystal layer 3A hardly changes before and after the formation of the second alignment film 2B, which controls the alignment of the second cholesteric liquid crystals 312, in the liquid crystal optical element 100, in which the second liquid crystal layer 3B comprising the second cholesteric liquid crystals 312 is disposed on the first liquid crystal layer 3A comprising the first cholesteric liquid crystals 311. In addition, in the second liquid crystal layer 3B, the second cholesteric liquid crystals 312 are configured to include the liquid crystal molecules which are controlled to align in a predetermined direction by the second alignment film 2B. Thus, desired reflective performance can be achieved.

In addition, in the first liquid crystal layer 3A, the liquid crystal molecules aligned in a predetermined direction before the formation of the second alignment film 2B are maintained in the state of being aligned in the predetermined direction also after the formation of the second alignment film 2B. Thus, undesirable scattering due to disorder in alignment of the liquid crystal molecules in the first liquid crystal layer 3A (or cloudiness of the first liquid crystal layer 3A) is suppressed. Accordingly, the decrease in the efficiency of light utilization in the liquid crystal optical element 100 can be suppressed.

In addition, according to Embodiment 1, the first cholesteric liquid crystals 311 and the second cholesteric liquid crystals 312 have an equal helical pitch and turn in directions opposite to each other. Thus, in the liquid crystal optical element 100, not only first circularly polarized light but also second circularly polarized light of the same selective reflection band (in the above example, infrared rays) can be guided, and the efficiency of light utilization can be further improved.

### Embodiment 2

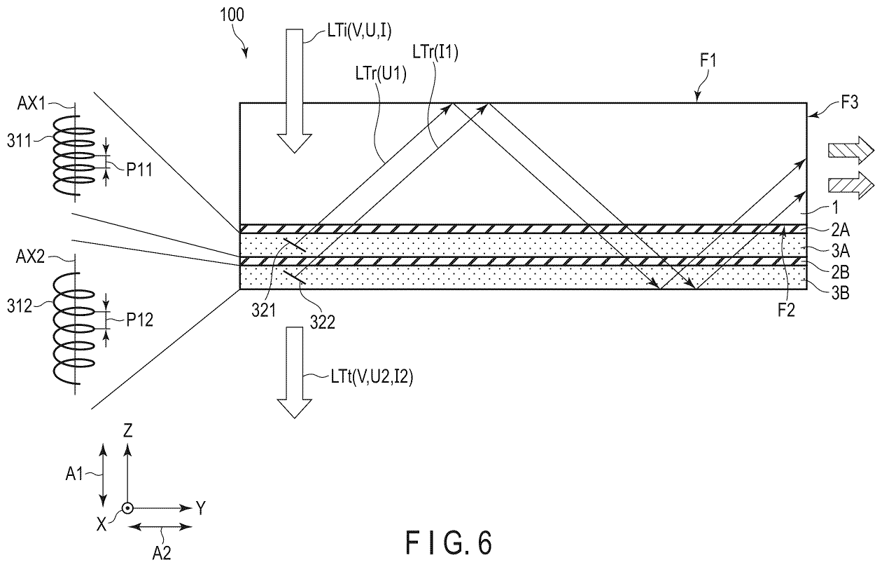

FIG. 6 is a cross-sectional view schematically illustrating a liquid crystal optical element 100 according to Embodiment 2.

Embodiment 2 illustrated in FIG. 6 is different from Embodiment 1 illustrated in FIG. 1 in that a helical pitch P11 of a first cholesteric liquid crystal 311 is different from a helical pitch P12 of a second cholesteric liquid crystal 312. The cross-sectional structure of the liquid crystal optical element 100 of Embodiment 2 is the same as that of Embodiment 1. That is, the liquid crystal optical element 100 is formed as the stacked layer body of an optical waveguide 1, a first alignment film 2A, a first liquid crystal layer 3A, a second alignment film 2B, and a second liquid crystal layer 3B.

In the example illustrated in the figure, the helical pitch P11 is smaller than the helical pitch P12. Note that the helical pitch P12 may be smaller than the helical pitch P11.

In the example illustrated in the figure, the turning direction of the first cholesteric liquid crystal 311 is the same as the turning direction of the second cholesteric liquid crystal 312. Note that the turning direction of the first cholesteric liquid crystal 311 may be opposite to the turning direction of the second cholesteric liquid crystal 312.

In the first liquid crystal layer 3A, the first cholesteric liquid crystal 311 forms a reflective surface 321 which reflects first circularly polarized light of a selective reflection band.

In the second liquid crystal layer 3B, the second cholesteric liquid crystal 312 forms a reflective surface 322 which reflects first circularly polarized light of a selective reflection band which is different from that of the first liquid crystal layer 3A.

For example, the first cholesteric liquid crystal 311 is formed to reflect ultraviolet rays U as the selective reflection band. That is, the first cholesteric liquid crystal 311 is configured to reflect first circularly polarized light U1 of ultraviolet rays U.

In addition, the second cholesteric liquid crystal 312 is formed to reflect infrared rays I as the selective reflection band. That is, the second cholesteric liquid crystal 312 is configured to reflect first circularly polarized light I1 of infrared rays I.

While the example in which ultraviolet rays U and infrared rays I are reflected has been described here, the first cholesteric liquid crystal 311 and the second cholesteric liquid crystal 312 may be configured to reflect visible light V.

The optical action of the liquid crystal optical element 100 in Embodiment 2 illustrated in FIG. 6 will be described next.

Light LTi incident on the liquid crystal optical element 100 includes, for example, visible light V, ultraviolet rays U, and infrared rays I.

Light LTi enters the inside of the optical waveguide 1 from a first main surface F1, is emitted from a second main surface F2, is transmitted through the first alignment film 2A, and is incident on the first liquid crystal layer 3A. Then, the first liquid crystal layer 3A reflects first circularly polarized light U1 of ultraviolet rays U of light LTi toward the optical waveguide 1 and transmits other light LTt.

Light LTt transmitted through the first liquid crystal layer 3A is transmitted through the second alignment film 2B and is incident on the second liquid crystal layer 3B. Then, the second liquid crystal layer 3B reflects first circularly polarized light I1 of infrared rays I of light LTt toward the optical waveguide 1 and transmits other light LTt. Light LTt transmitted through the second liquid crystal layer 3B includes visible light V, second circularly polarized light U2 of ultraviolet rays U, and second circularly polarized light 12 of infrared rays I.

If the optical waveguide 1, the first alignment film 2A, the first liquid crystal layer 3A, the second alignment film 2B, and the second liquid crystal layer 3B have equivalent refractive indices, the stacked layer body of these can be a single optical waveguide body. In this case, light LTr is guided toward a side surface F3 while being reflected repeatedly at the interface between the optical waveguide 1 and the air and the interface between the second liquid crystal layer 3B and the air.

In Embodiment 2, too, the same advantages as those of Embodiment 1, described above, are achieved. In addition, the selective reflection band of the liquid crystal optical element 100 can be widened.

### Embodiment 3

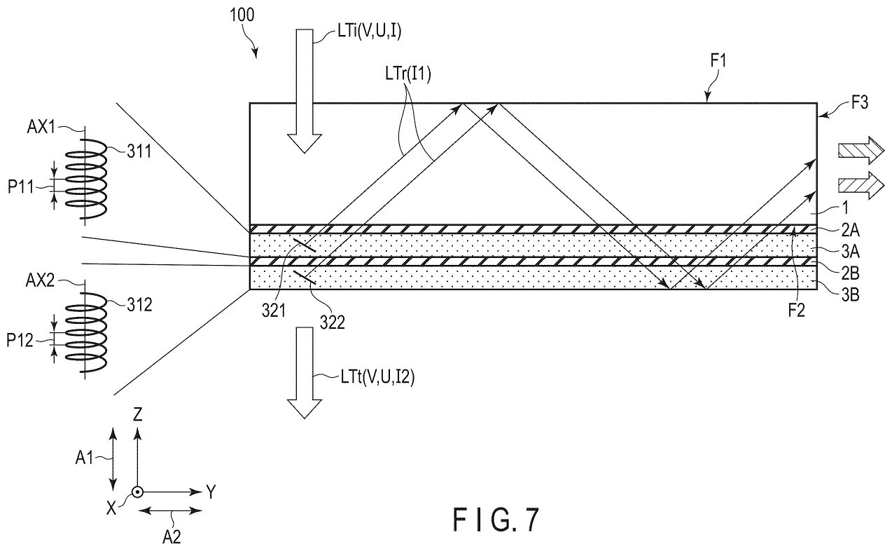

FIG. 7 is a cross-sectional view schematically illustrating a liquid crystal optical element 100 according to Embodiment 3.

Embodiment 3 illustrated in FIG. 7 is different from Embodiment 1 illustrated in FIG. 1 in that a helical pitch P11 of a first cholesteric liquid crystal 311 is equal to a helical pitch P12 of a second cholesteric liquid crystal 312 and the first cholesteric liquid crystal 311 and the second cholesteric liquid crystal 312 turn in the same direction. The cross-sectional structure of the liquid crystal optical element 100 of Embodiment 3 is the same as that of Embodiment 1, and the liquid crystal optical element 100 is formed as the stacked layer body of an optical waveguide 1, a first alignment film 2A, a first liquid crystal layer 3A, a second alignment film 2B, and a second liquid crystal layer 3B.

In the first liquid crystal layer 3A, the first cholesteric liquid crystal 311 forms a reflective surface 321 which reflects first circularly polarized light of a selective reflection band.

In the second liquid crystal layer 3B, the second cholesteric liquid crystal 312 forms a reflective surface 322 which reflects first circularly polarized light of the selective reflection band.

For example, the first cholesteric liquid crystal 311 and the second cholesteric liquid crystal 312 are both formed to reflect to infrared rays I as the selective reflection band. That is, the first cholesteric liquid crystal 311 and the second cholesteric liquid crystal 312 are configured to reflect first circularly polarized light I1 of infrared rays I.

While the example in which infrared rays I are reflected has been described here, the first cholesteric liquid crystal 311 and the second cholesteric liquid crystal 312 may be configured to reflect visible light V and ultraviolet rays U.

The optical action of the liquid crystal optical element 100 in Embodiment 3 illustrated in FIG. 7 will be described next.

Light LTi incident on the liquid crystal optical element 100 includes, for example, visible light V, ultraviolet rays U, and infrared rays I.

Light LTi enters the inside of the optical waveguide 1 from a first main surface F1, is emitted from a second main surface F2, is transmitted through the first alignment film 2A, and is incident on the first liquid crystal layer 3A. Then, the first liquid crystal layer 3A reflects first circularly polarized light I1 of infrared rays I of light LTi toward the optical waveguide 1 and transmits other light LTt.

Light LTt transmitted through the first liquid crystal layer 3A is transmitted through the second alignment film 2B and is incident on the second liquid crystal layer 3B. Then, the second liquid crystal layer 3B reflects first circularly polarized light I1 of infrared rays I transmitted through the first liquid crystal layer 3A of light LTt toward the optical waveguide 1, and transmits other light LTt. Light LTt transmitted through the second liquid crystal layer 3B includes visible light V, ultraviolet rays U, and second circularly polarized light 12 of infrared rays I.

If the optical waveguide 1, the first alignment film 2A, the first liquid crystal layer 3A, the second alignment film 2B, and the second liquid the stacked layer body of these can be a single optical waveguide body. In this case, light LTr is guided toward a side surface F3 while being reflected repeatedly at the interface between the optical waveguide 1 and the air and the interface between the second liquid crystal layer 3B and the air.

In Embodiment 3, too, the same advantages as those of Embodiment 1, described above, are achieved. In addition, the reflectance for the selective reflection band of the liquid crystal optical element 100 can be improved.

If the first liquid crystal layer 3A overlapping the first alignment film 2A is a thick film, the alignment restriction force decreases in a direction away from the first alignment film 2A and the helical pitch may enlarge.

In contrast, according to Embodiment 3, the multilayer structure of the first alignment film 2A, the first liquid crystal layer 3A, the second alignment film 2B, and the second liquid crystal layer 3B is adopted, so that each of the first liquid crystal layer 3A and the second liquid crystal layer 3B can have a desired helical pitch. Accordingly, the undesirable shift of the selective reflection band can be suppressed.

In addition, if the multilayer structure is adopted such that the first liquid crystal layer 3A and the second liquid crystal layer 3B contact each other, the components of the second liquid crystal layer 3B easily penetrate the first liquid crystal layer 3A, which may cause the enlargement of the helical pitch of the first cholesteric liquid crystal 311 and cloudiness due to disorder in alignment of liquid crystal molecules.

In contrast, according to Embodiment 3, the second alignment film 2B is interposed between the first liquid crystal layer 3A and the second liquid crystal layer 3B, and suppresses the penetration of the first liquid crystal layer 3A by the components of the second alignment film 2B and the components of the second liquid crystal layer 3B. Accordingly, the undesirable shift of the selective reflection band can be suppressed, and the decrease in the efficiency of light utilization can be suppressed.

### Embodiment 4

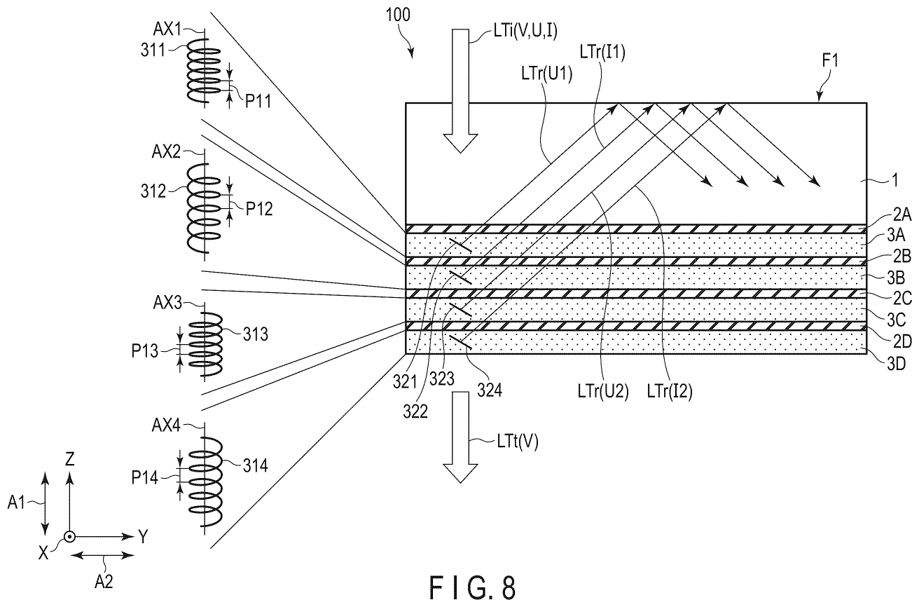

FIG. 8 is a cross-sectional view schematically illustrating a liquid crystal optical element 100 according to Embodiment 4.

Embodiment 4 illustrated in FIG. 8 is different from Embodiment 2 illustrated in FIG. 6 in that the liquid crystal optical element 100 further comprises a third alignment film 2C, a third liquid crystal layer 3C, a fourth alignment film 2D, and a fourth liquid crystal layer 3D. That is, the liquid crystal optical element 100 is formed as the stacked layer body of an optical waveguide 1, a first alignment film 2A, a first liquid crystal layer 3A, a second alignment film 2B, a second liquid crystal layer 3B, the third alignment film 2C, the third liquid crystal layer 3C, the fourth alignment film 2D, and the fourth liquid crystal layer 3D.

The third alignment film 2C overlaps the second liquid crystal layer 3B in the first direction A1. That is, the second liquid crystal layer 3B is located between the second alignment film 2B and the third alignment film 2C, and contacts the second alignment film 2B and the third alignment film 2C.

The third liquid crystal layer 3C overlaps the third alignment film 2C in the first direction A1. That is, the third alignment film 2C is located between the second liquid crystal layer 3B and the third liquid crystal layer 3C, and contacts the second liquid crystal layer 3B and the third liquid crystal layer 3C.

The fourth alignment film 2D overlaps the third liquid crystal layer 3C in the first direction A1. That is, the third liquid crystal layer 3C is located between the third alignment film 2C and the fourth alignment film 2D, and contacts the third alignment film 2C and the fourth alignment film 2D.

The fourth liquid crystal layer 3D overlaps the fourth alignment film 2D in the first direction A1. That is, the fourth alignment film 2D is located between the third liquid crystal layer 3C and the fourth liquid crystal layer 3D, and contacts the third liquid crystal layer 3C and the fourth liquid crystal layer 3D.

The third alignment film 2C and the fourth alignment film 2D are horizontal alignment films having alignment restriction force along the X-Y plane. In addition, the third alignment film 2C and the fourth alignment film 2D are, for example, optical alignment films for which alignment treatment can be performed by light irradiation, but may be alignment films for which alignment treatment is performed by rubbing or may be alignment films having minute irregularities. The materials that can be applied as the optical alignment films are as described in Embodiment 1.

The third liquid crystal layer 3C comprises a third cholesteric liquid crystal 313 turning in a second turning direction. The third cholesteric liquid crystal 313 has a helical axis AX3 substantially parallel to the first direction A1 and has a helical pitch P13 in the first direction A1. The helical pitch P13 is equal to a helical pitch P11.

The fourth liquid crystal layer 3D comprises a fourth cholesteric liquid crystal 314 turning in the second turning direction. The fourth cholesteric liquid crystal 314 has a helical axis AX4 substantially parallel to the first direction A1 and has a helical pitch P14 in the first direction A1. The helical pitch P14 is equal to a helical pitch P12 and is greater than the helical pitch P13.

A helical axis AX1, a helical axis AX2, the helical axis AX3, and the helical axis AX4 are parallel to each other.

In the third liquid crystal layer 3C, the third cholesteric liquid crystal 313 forms a reflective surface 323 which reflects second circularly polarized light corresponding to the second turning direction of a selective reflection band.

In the fourth liquid crystal layer 3D, the fourth cholesteric liquid crystal 314 forms a reflective surface 324 which reflects second circularly polarized light of a selective reflection band.

For example, a first cholesteric liquid crystal 311 and the third cholesteric liquid crystal 313 are both formed to reflect ultraviolet rays U as the selective reflection band. That is, the first cholesteric liquid crystal 311 is configured to reflect first circularly polarized light U1 of ultraviolet rays U, and the third cholesteric liquid crystal 313 is configured to reflect second circularly polarized light U2 of ultraviolet rays U.

In addition, a second cholesteric liquid crystal 312 and the fourth cholesteric liquid crystal 314 are both formed to reflect infrared rays I as the selective reflection band. That is, the second cholesteric liquid crystal 312 is configured to reflect first circularly polarized light I1 of infrared rays I, and the fourth cholesteric liquid crystal 314 is configured to reflect second circularly polarized light 12 of infrared rays I.

The optical action of the liquid crystal optical element 100 in Embodiment 4 illustrated in FIG. 8 will be described next.

Light LTi incident on the liquid crystal optical element 100 includes, for example, visible light V, ultraviolet rays U, and infrared rays I.

Light LTi enters the inside of the optical waveguide 1 from a first main surface F1, is emitted from a second main surface F2, is transmitted through the first alignment film 2A, and is incident on the first liquid crystal layer 3A. Then, the first liquid crystal layer 3A reflects first circularly polarized light U1 of ultraviolet rays U of light LTi toward the optical waveguide 1 and transmits other light LTt.

Light LTt transmitted through the first liquid crystal layer 3A is transmitted through the second alignment film 2B and is incident on the second liquid crystal layer 3B. Then, the second liquid crystal layer 3B reflects first circularly polarized light I1 of infrared rays I of light LTt toward the optical waveguide 1 and transmits other light LTt.

Light LTt transmitted through the second liquid crystal layer 3B is transmitted through the third alignment film 2C and is incident on the third liquid crystal layer 3C. Then, the third liquid crystal layer 3C reflects second circularly polarized light U2 of ultraviolet rays U of light LTt toward the optical waveguide 1 and transmits other light LTt.

Light LTt transmitted through the third liquid crystal layer 3C is transmitted through the fourth alignment film 2D and is incident on the fourth liquid crystal layer 3D. Then, the fourth liquid crystal layer 3D reflects second circularly polarized light 12 of infrared rays I of light LTt toward the optical waveguide 1 and transmits other light LTt. Light LTt transmitted through the fourth liquid crystal layer 3D includes visible light V.

If the optical waveguide 1, the first alignment film 2A, the first liquid crystal layer 3A, the second alignment film 2B, the second liquid crystal layer 3B, the third alignment film 2C, the third liquid crystal layer 3C, the fourth alignment film 2D, and the fourth liquid crystal layer 3D have equivalent refractive indices, the stacked layer body of these can be a single optical waveguide body. In this case, light LTr is guided toward a side surface F3 while being reflected repeatedly at the interface between the optical waveguide 1 and the air and the interface between the fourth liquid crystal layer 3D and the air.

In Embodiment 4, too, the selective reflection band of the liquid crystal optical element 100 can be widened as in Embodiment 2, described above. In addition, the liquid crystal optical element 100 can guide first circularly polarized light and second circularly polarized light of a first selective reflection band (ultraviolet rays in the above-described example) and can guide first circularly polarized light and second circularly polarized light of a second selective reflection band (infrared rays in the above-described example) different from the first selective reflection band, so that the efficiency of light utilization can be further improved.

### Embodiment 5

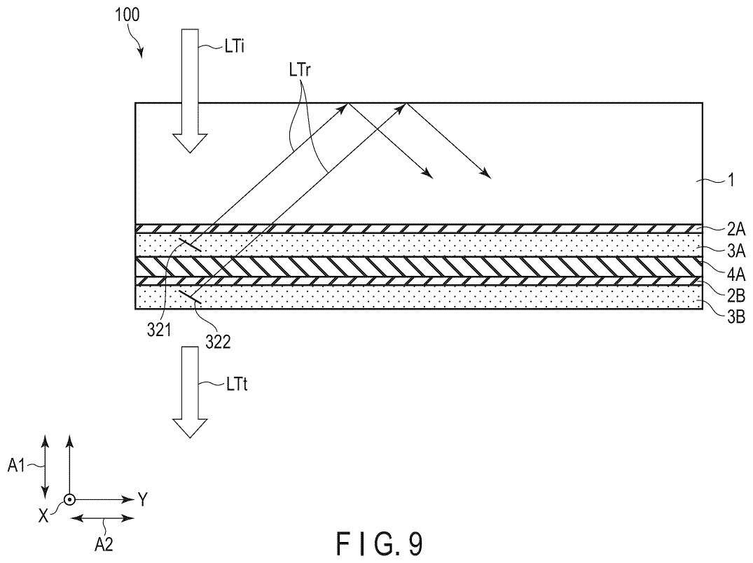

FIG. 9 is a cross-sectional view schematically illustrating a liquid crystal optical element 100 according to Embodiment 5.

Embodiment 5 illustrated in FIG. 9 is different from Embodiment 1 illustrated in FIG. 1 in that a protective layer 4A is provided between a first liquid crystal layer 3A and a second alignment film 2B. That is, the protective layer 4A overlaps the first liquid crystal layer 3A, the second alignment film 2B overlaps the protective layer 4A, and the protective layer 4A contacts the first liquid crystal layer 3A and the second alignment film 2B. The liquid crystal optical element 100 is formed as the stacked layer body of an optical waveguide 1, a first alignment film 2A, the first liquid crystal layer 3A, the protective layer 4A, the second alignment film 2B, and a second liquid crystal layer 3B.

The protective layer 4A is transparent and has high optical transparency especially to visible light. The protective layer 4A is formed of a water-soluble polymer, an organic film, or an inorganic film.

As the water-soluble polymer, synthetic polymers, such as sodium polyacrylate, polyacrylamide, polyvinyl alcohol, polyethyleneimine, polyethylene oxide, and polyvinylpyrrolidone, can be applied, for example. In addition, as other examples of the water-soluble polymer, cellulosic semi-synthetic polymers, such as carboxymethyl cellulose, hydroxyethyl cellulose, and hydroxypropyl cellulose, can be applied. Moreover, as other examples of the water-soluble polymer, starch-based semi-synthetic polymers, such as oxidized starch and modified starch, can be applied.

As the organic film, polyvinyl chloride (PVC), polyethylene (PE), cast polypropylene (CPP), biaxially-oriented polypropylene (OPP), biaxially-oriented polystyrene (OPS), polyvinylidene chloride (PVDC), acrylic resin, polyethylene terephthalate (PET), triacetylcellulose (TAC), polycarbonate (PC), aramid, polyethersulfone (PES), polyphenylene sulfide (PPS), polyimide (PI), polyurethane, fluorine resin, norbornene resin, cycloolefin-based resin can be applied, for example.

In addition, as the inorganic film, silicon nitride (SiNx) and silicon oxide (SiOx) can be applied, for example.

Of these materials, acrylic resin, triacetylcellulose, hydroxypropyl cellulose, and polyvinyl alcohol are preferable in terms of handleability.

The relationship between the thicknesses of the thin films constituting the liquid crystal optical element 100 is as follows.

The respective thicknesses of the first alignment film 2A and the second alignment film 2B are 5 nm to 300 nm and should preferably be 10 nm to 200 nm.

The respective thicknesses of the first liquid crystal layer 3A and the second liquid crystal layer 3B are 1 μm to 10 μm and should preferably be 2 μm to 7 μm.

The thickness of the protective layer 4A is greater than the respective thicknesses of the first alignment film 2A and the second alignment film 2B. If the protective layer 4A is an organic film, the thickness of the protective layer 4A is 1 μm to 1,000 μm and should preferably be 2 μm to 100 μm.

If the protective layer 4A is an inorganic film, the thickness of the protective layer 4A is 10 nm to 10 μm and should preferably be 50 nm to 5 μm.

The first liquid crystal layer 3A comprises a first cholesteric liquid crystal 311 illustrated in any one of FIG. 1, FIG. 6, and FIG. 7, and forms a reflective surface 321 which reflects first circularly polarized light or second circularly polarized light of a selective reflection band.

The second liquid crystal layer 3B comprises a second cholesteric liquid crystal 312 illustrated in any one of FIG. 1, FIG. 6, and FIG. 7, and forms a reflective surface 322 which reflects first circularly polarized light or second circularly polarized light of the selective reflection band.

In Embodiment 5, too, the same advantages as those of Embodiment 1, described above, are achieved. In addition, since the second alignment film 2B does not contact the first liquid crystal layer 3A, the options for the material forming the second alignment film 2B can be broadened. Moreover, as compared to the case where an alignment film material for forming the second alignment film 2B is applied to the surface of the first liquid crystal layer 3A, the wettability of the alignment film material is enhanced and the uniformity of the film thickness of the second alignment film 2B is improved.

### Embodiment 6

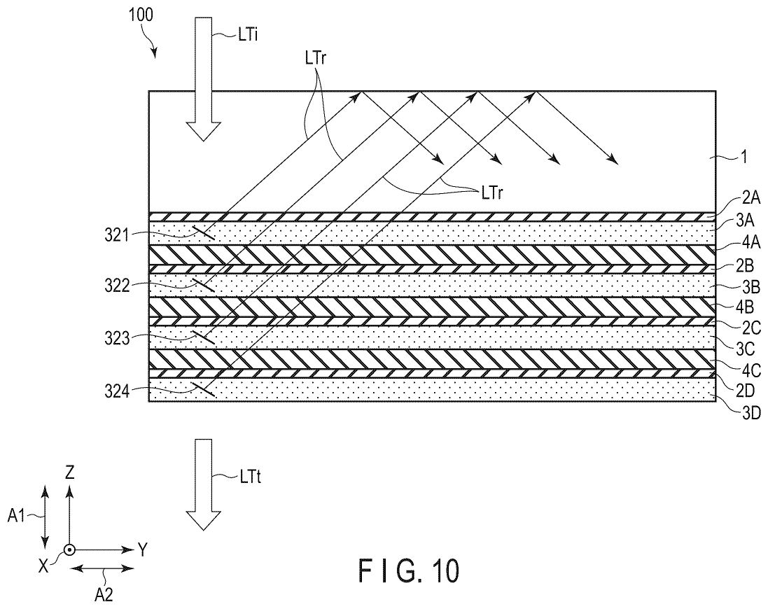

FIG. 10 is a cross-sectional view schematically illustrating a liquid crystal optical element 100 according to Embodiment 6.

Embodiment 6 illustrated in FIG. 10 is different from Embodiment 5 illustrated in FIG. 9 in that the liquid crystal optical element 100 further comprises a protective layer 4B, a third alignment film 2C, a third liquid crystal layer 3C, a protective layer 4C, a fourth alignment film 2D, and a fourth liquid crystal layer 3D. That is, the liquid crystal optical element 100 is formed as the stacked layer body of an optical waveguide 1, a first alignment film 2A, a first liquid crystal layer 3A, a protective layer 4A, a second alignment film 2B, a second liquid crystal layer 3B, the protective layer 4B, the third alignment film 2C, the third liquid crystal layer 3C, the protective layer 4C, the fourth alignment film 2D, and the fourth liquid crystal layer 3D.

As the materials forming the protective layers 4A, 4B, and 4C, the above-described materials can be applied. The protective layers 4A, 4B, and 4C may be formed of the same material or may be formed of materials different from each other.

The third liquid crystal layer 3C comprises, for example, a third cholesteric liquid crystal 313 illustrated in FIG. 8, and forms a reflective surface 323 which reflects first circularly polarized light or second circularly polarized light of a selective reflection band.

The fourth liquid crystal layer 3D comprises, for example, a fourth cholesteric liquid crystal 314 illustrated in FIG. 8, and forms a reflective surface 324 which reflects first circularly polarized light or second circularly polarized light of the selective reflection band.

In Embodiment 6, too, the same advantages as those of Embodiment 5, described above, are achieved. In addition, the selective reflection band can be widened, and the efficiency of light utilization can be further improved.

A photovoltaic cell device 200 will be described next as an application example of the liquid crystal optical elements 100 according to the present embodiments.

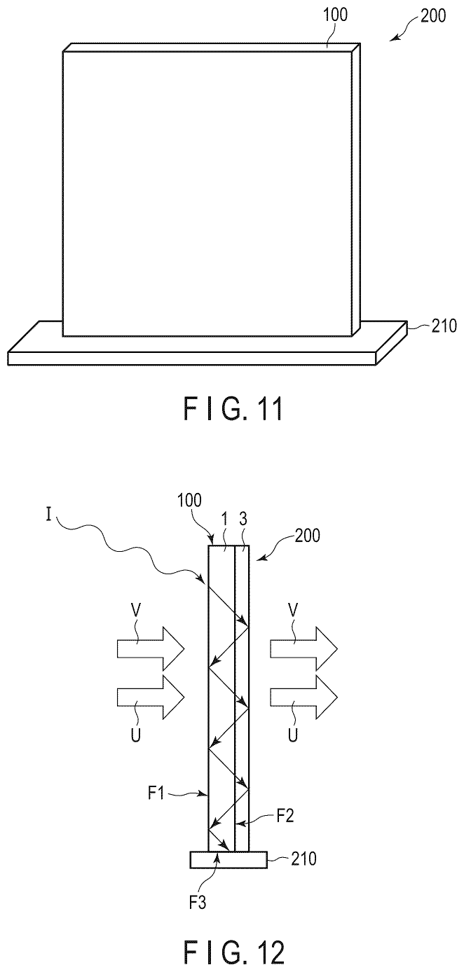

FIG. 11 is a diagram illustrating an example of the outside of the photovoltaic cell device 200.

The photovoltaic cell device 200 comprises any one of the above-described liquid crystal optical elements 100 and a power generation device 210. The power generation device 210 is provided along one side of the liquid crystal optical element 100. The one side of the liquid crystal optical element 100, which is opposed to the power generation device 210, is a side along the side surface F3 of the optical waveguide 1 illustrated in FIG. 1, etc. In the photovoltaic cell device 200, the liquid crystal optical element 100 functions as a lightguide element which guides light of a predetermined wavelength to the power generation device 210.

The power generation device 210 comprises a plurality of photovoltaic cells. The photovoltaic cells receive light and convert the energy of received light into power. That is, the photovoltaic cells generate power from received light. The types of photovoltaic cell are not particularly limited. For example, the photovoltaic cells are silicon photovoltaic cells, compound photovoltaic cells, organic photovoltaic cells, perovskite photovoltaic cells, or quantum dot photovoltaic cells. The silicon photovoltaic cells include photovoltaic cells comprising amorphous silicon, photovoltaic cells comprising polycrystalline silicon, etc.

FIG. 12 is a diagram for explaining the operation of the photovoltaic cell device 200.

The first main surface F1 of the optical waveguide 1 faces outdoors. A liquid crystal layer 3 faces indoors. In FIG. 12, the illustration of an alignment film and the like is omitted.

The liquid crystal layer 3 is, for example, configured to reflect first circularly polarized light I1 and second circularly polarized light 12 of infrared rays I as illustrated in FIG. 1. The liquid crystal layer 3 may be configured to reflect first circularly polarized light I1 of infrared rays I and first circularly polarized light U1 of ultraviolet rays U as illustrated in FIG. 6, or may be configured to reflect first circularly polarized light I1 of infrared rays I and to transmit second circularly polarized light 12 as illustrated in FIG. 7, or may be configured to reflect first circularly polarized light I1 and second circularly polarized light 12 of infrared rays I and to reflect first circularly polarized light U1 and second circularly polarized light U2 of ultraviolet rays U as illustrated in FIG. 8. In addition, the liquid crystal layer 3 may include one or more protective layers as illustrated in FIG. 9 and FIG. 10.

Infrared rays I reflected by the liquid crystal layer 3 propagate through the liquid crystal optical element 100 toward the side surface F3. The power generation device 210 receives infrared rays I transmitted through the side surface F3 and generates power.

Visible light V and ultraviolet rays U of solar light are transmitted through the liquid crystal optical element 100. In particular, a first component (blue component), a second component (green component), and a third component (red component), which are main components of visible light V, are transmitted through the liquid crystal optical element 100. Thus, the coloration of light transmitted through the photovoltaic cell device 200 can be suppressed. In addition, the decrease in the transmittance of visible light V in the photovoltaic cell device 200 can be suppressed.

As described above, according to the present embodiments, a liquid crystal optical element which can achieve desired reflective performance can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A liquid crystal optical element comprising:
an optical waveguide comprising a first main surface and a second main surface opposed to the first main surface;
a first alignment film disposed on the second main surface;
a first liquid crystal layer which overlaps the first alignment film, which comprises a first cholesteric liquid crystal, and which reflects at least part of light incident through the optical waveguide toward the optical waveguide;
a second alignment film which overlaps the first liquid crystal layer; and
a second liquid crystal layer which overlaps the second alignment film, which comprises a second cholesteric liquid crystal, and which reflects at least part of light incident through the optical waveguide toward the optical waveguide.

2. The liquid crystal optical element of claim 1, wherein the first alignment film and the second alignment film are optical alignment films of any one of a photodecomposition type, a photodimerization type, and a photoisomerization type.

3. The liquid crystal optical element of claim 1, wherein the first cholesteric liquid crystal and the second cholesteric liquid crystal have an equal helical pitch and turn in directions opposite to each other.

4. The liquid crystal optical element of claim 1, wherein the first cholesteric liquid crystal and the second cholesteric liquid crystal have different helical pitches.

5. The liquid crystal optical element of claim 1, wherein the first cholesteric liquid crystal and the second cholesteric liquid crystal have an equal helical pitch and turn in the same direction.

6. The liquid crystal optical element of claim 1, further comprising:
a third alignment film which overlaps the second liquid crystal layer;
a third liquid crystal layer which overlaps the third alignment film, which comprises a third cholesteric liquid crystal, and which reflects at least part of light incident through the optical waveguide toward the optical waveguide;
a fourth alignment film which overlaps the third liquid crystal layer; and
a fourth liquid crystal layer which overlaps the fourth alignment film, which comprises a fourth cholesteric liquid crystal, and which reflects at least part of light incident through the optical waveguide toward the optical waveguide, wherein
the first cholesteric liquid crystal and the third cholesteric liquid crystal have an equal helical pitch and turn in directions opposite to each other,
the second cholesteric liquid crystal and the fourth cholesteric liquid crystal have an equal helical pitch and turn in directions opposite to each other, and
the first cholesteric liquid crystal and the second cholesteric liquid crystal have different helical pitches.

7. A liquid crystal optical element comprising:
an optical waveguide comprising a first main surface and a second main surface opposed to the first main surface;
a first alignment film disposed on the second main surface;
a first liquid crystal layer which overlaps the first alignment film, which comprises a first cholesteric liquid crystal, and which reflects at least part of light incident through the optical waveguide toward the optical waveguide;
a protective layer which overlaps the first liquid crystal layer;
a second alignment film which overlaps the protective layer; and
a second liquid crystal layer which overlaps the second alignment film, which comprises a second cholesteric liquid crystal, and which reflects at least part of light incident through the optical waveguide toward the optical waveguide.

8. The liquid crystal optical element of claim 7, wherein the protective layer is formed of polyvinyl alcohol.

9. The liquid crystal optical element of claim 7, wherein the first alignment film and the second alignment film are optical alignment films of any one of a photodecomposition type, a photodimerization type, and a photoisomerization type.

10. The liquid crystal optical element of claim 7, wherein the first cholesteric liquid crystal and the second cholesteric liquid crystal have an equal helical pitch and turn in directions opposite to each other.

11. The liquid crystal optical element of claim 7, wherein the first cholesteric liquid crystal and the second cholesteric liquid crystal have different helical pitches.

12. The liquid crystal optical element of claim 7, wherein the first cholesteric liquid crystal and the second cholesteric liquid crystal have an equal helical pitch and turn in the same direction.

13. A liquid crystal optical element comprising:
an optical waveguide comprising a first main surface and a second main surface opposed to the first main surface;
a first alignment film disposed on the second main surface;
a first liquid crystal layer which overlaps the first alignment film, which comprises a first cholesteric liquid crystal, and which reflects at least part of light incident through the optical waveguide toward the optical waveguide;
a first protective layer which overlaps the first liquid crystal layer;
a second alignment film which overlaps the first protective layer;
a second liquid crystal layer which overlaps the second alignment film, which comprises a second cholesteric liquid crystal, and which reflects at least part of light incident through the optical waveguide toward the optical waveguide;
a second protective layer which overlaps the second liquid crystal layer;
a third alignment film which overlaps the second protective layer;
a third liquid crystal layer which overlaps the third alignment film, which comprises a third cholesteric liquid crystal, and which reflects at least part of light incident through the optical waveguide toward the optical waveguide;
a third protective layer which overlaps the third liquid crystal layer;
a fourth alignment film which overlaps the third protective layer; and
a fourth liquid crystal layer which overlaps the fourth alignment film, which comprises a fourth cholesteric liquid crystal, and which reflects at least part of light incident through the optical waveguide toward the optical waveguide.

14. The liquid crystal optical element of claim 13, wherein
the first cholesteric liquid crystal and the third cholesteric liquid crystal have an equal helical pitch and turn in directions opposite to each other,
the second cholesteric liquid crystal and the fourth cholesteric liquid crystal have an equal helical pitch and turn in directions opposite to each other, and
the first cholesteric liquid crystal and the second cholesteric liquid crystal have different helical pitches.

15. The liquid crystal optical element of claim 13, wherein the first protective layer, the second protective layer, and the third protective layer are formed of polyvinyl alcohol.

16. The liquid crystal optical element of claim 13, wherein the first alignment film, the second alignment film, the third alignment film, and the fourth alignment film are optical alignment films of any one of a photodecomposition type, a photodimerization type, and a photoisomerization type.
